(19) United States
(12) Patent Application Publication
(10) Pub. No.: US 2025/0070089 A1
(43) Pub. Date: Feb. 27, 2025

(54) 3-DIMENSIONAL ELECTRONIC DEVICE AND METHOD FOR MANUFACTURING THE SAME

(71) Applicant: ELECTRONICS AND TELECOMMUNICATIONS RESEARCH INSTITUTE, Daejeon (KR)

(72) Inventors: Yong Suk Yang, Daejeon (KR); Myung Lae Lee, Daejeon (KR); Jengsu Yoo, Daejeon (KR); Yoonsik Yi, Daejeon (KR)

(21) Appl. No.: 18/750,090

(22) Filed: Jun. 21, 2024

(30) Foreign Application Priority Data
Aug. 24, 2023 (KR) 10-2023-0111131

(51) Int. Cl. H01L 25/065; H01L 25/00

(52) U.S. Cl. CPC H01L 25/0657; H01L 25/50; H01L 2225/06506; H01L 2225/06551; H01L 2225/06582

(57) ABSTRACT

Provided are a 3-dimensional electronic device and a method for manufacturing the 3-dimensional electronic device. The method includes coupling semiconductor chips and guide blocks onto a substrate, forming an upper mold layer and upper wires on the semiconductor chips and the guide blocks by using a 3D printing method, stacking substrates other than the substrate on the upper mold layer and the upper wires, sawing a portion of each of the guide blocks and the upper mold layer, and forming a side mold layer and side wires on sidewalls of via electrodes of the guide blocks by using the 3D printing method.

### CROSS-REFERENCE TO RELATED APPLICATIONS

This U.S. non-provisional patent application claims priority under 35 U.S.C. § 119 of Korean Patent Application No. 10-2023-0111131, filed on Aug. 24, 2023, the entire contents of which are hereby incorporated by reference.

### BACKGROUND

The present disclosure herein relates to an electronic device and a method for manufacturing the same, and more particularly, to a 3-dimensional electronic device and a method for manufacturing the same.

Space and aviation applications increasingly require electronic circuit modules such as RF, analog, and power devices, in addition to high-capacity, high-speed, and compact mass memories. A major barrier to the adoption of “commercial off-the-shelf (COTS)” devices, which refer to commercially available off-the-shelf apparatuses for use in military and space applications, is known as radiological threat to active electronic components. Not only these radiation-induced errors but also vibrations or heat, which are applied to electronic apparatuses under different situations from existing use environment, cause failures of operations of products.

Existing methods for collective manufacturing 3D electronic modules of electronic devices for space and aviation are developed by advanced companies worldwide such as Microchip Technology, 3D-Plus, Cobham, Honeywell, and DDC. A panel module is formed mainly through manufacture of a stack including a redistribution layer that connects a semiconductor chip and a PCB or interposer, verified for space and aviation based on wire bonding, bonding to a substrate having a TSOP portion, and molding of a circuit mounted with an electrical insulation resin. However, the vertical formation of the circuit of this stacked 3D electronic module follows fabrication through simply plating and patterning a metal material along a molding wall surface. This is a simple manufacturing process, but a line width of a wire is large, a wiring structure is simple, and there is a limit to avoid the radiological threat.

### SUMMARY

The present disclosure provides a method for manufacturing a 3-dimensional electronic device capable of increasing a production yield.

An embodiment of the inventive concept provides a method for manufacturing a 3-dimensional electronic device, the method including coupling semiconductor chips and guide blocks onto a substrate, forming an upper mold layer and upper wires on the semiconductor chips and the guide blocks by using a 3D printing method, stacking substrates other than the substrate on the upper mold layer and the upper wires, sawing a portion of each of the guide blocks and the upper mold layer, and forming a side mold layer and side wires on sidewalls of via electrodes of the guide blocks by using the 3D printing method.

In an embodiment, the semiconductor chips may have pads that are exposed from the substrate.

In an embodiment, the coupling of the guide blocks may include forming an adhesive layer between sidewalls of the substrate and the guide blocks.

In an embodiment, the upper mold layer may have upper air holes between the semiconductor chips.

In an embodiment, the side mold layer may have side air holes on a sidewall of the upper mold layer.

In an embodiment, each of the side air holes may have a larger size than each of the upper air holes.

In an embodiment, the method may further include forming side caps, which define the side air holes, respectively, on the sidewall of the upper mold layer.

In an embodiment, the side caps may be provided between the via electrodes.

In an embodiment, the method may further include providing upper caps, which define the upper air holes, respectively, between the semiconductor chips.

In an embodiment, the method may further include forming sacrificial layers on sidewalls of the guide blocks and the upper mold layer.

In an embodiment of the inventive concept, a 3-dimensional electronic device includes a plurality of substrates, semiconductor chips on each of the plurality of substrates, guide blocks provided on sidewalls of the substrates and having via electrodes, upper mold layers provided between the semiconductor chips and the substrates, upper wires, which is provided within the upper mold layers and connects the semiconductor chips to each other, side mold layers on sidewalls of the upper mold layers and the guide blocks, and side wires which is provided within the side mold layers and connects the via electrodes of the guide blocks to each other.

In an embodiment, the semiconductor chips may have pads that are exposed from the substrate.

In an embodiment, the 3-dimensional electronic device may further include an adhesive layer between the sidewalls of the substrate and the guide blocks.

In an embodiment, each of the upper mold layers may have upper air holes between the semiconductor chips.

In an embodiment, the side mold layer may have side air holes on the sidewall of the upper mold layer.

In an embodiment, each of the side air holes may have a larger size than each of the upper air holes.

In an embodiment, the 3-dimensional electronic device may further include side caps that are provided on the sidewall of the upper mold layer and define the side air holes, respectively.

In an embodiment, the side caps may be provided between the via electrodes.

In an embodiment, the 3-dimensional electronic device may further include upper caps that are provided between the semiconductor chips and define the upper air holes, respectively.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart illustrating a method for manufacturing a 3-dimensional electronic device according to an embodiment of the inventive concept;

FIGS. 2, 3, 4, 5, 6, and 7 are cross-sectional views illustrating a process of a method for manufacturing a 3-dimensional electronic device according to an embodiment of the inventive concept;

FIGS. 8 and 9 are cross-sectional views illustrating an example of semiconductor chips in FIG. 2;

FIG. 10 is a perspective view illustrating an example of a guide block in FIG. 2;

FIG. 11 is a flowchart illustrating a method for manufacturing a 3-dimensional electronic device according to an embodiment of the inventive concept; and

FIGS. 12, 13, 14, 15, 16, 17, and 18 are cross-sectional views illustrating a process of a method for manufacturing a 3-dimensional electronic device according to an embodiment of the inventive concept.

### DETAILED DESCRIPTION

Hereinafter, embodiments of the inventive concept will be described in detail with reference to the accompanying drawings. Advantages and features of the present invention, and implementation methods thereof will be clarified through following embodiments described in detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be further understood that the terms “comprises” and/or “comprising”, when used in this specification, specify the presence of stated components, operations, and/or elements, but do not preclude the presence or addition of one or more other components, operations, and/or elements. Since preferred embodiments are provided below, the order of the reference numerals given in the description is not limited thereto.

Additionally, the embodiments herein will be described with reference to cross-sectional views and/or plan views as ideal exemplary views of the present invention. In the drawings, the thicknesses of layers and regions are exaggerated for effective description of the technical contents. Accordingly, shapes of the exemplary views may be modified according to manufacturing techniques and/or allowable errors. Therefore, the embodiments of the inventive concept are not limited to the specific shape illustrated in the views, but may include other shapes created according to manufacturing processes.

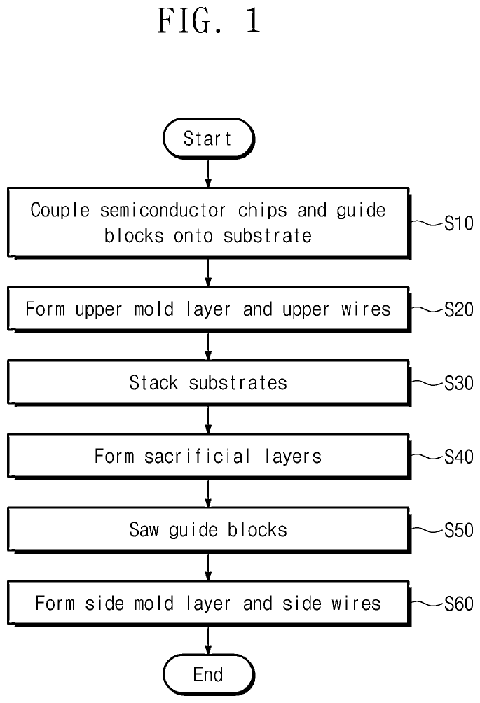

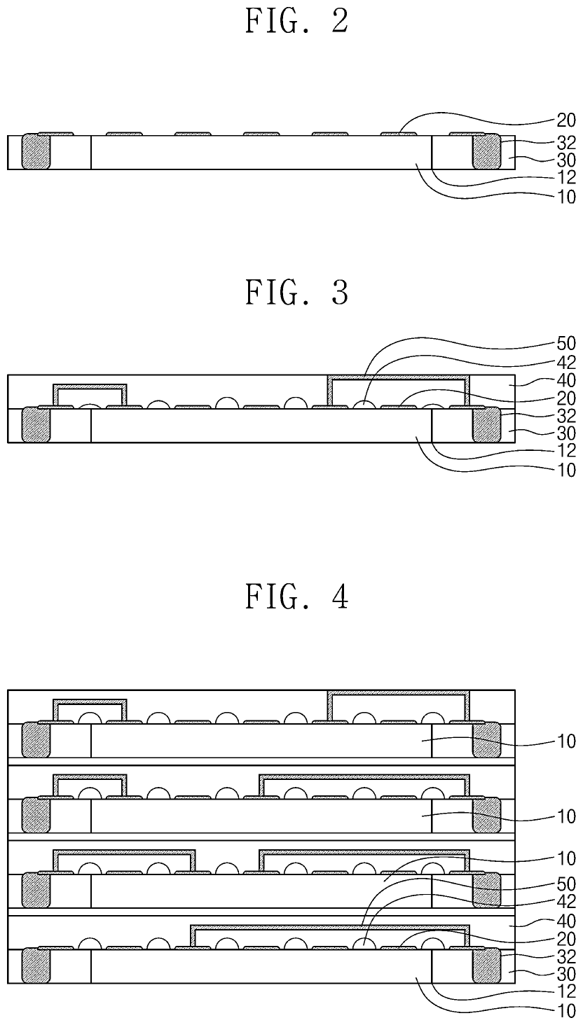

FIG. 1 illustrates a method for manufacturing a 3-dimensional electronic device according to an embodiment of the inventive concept. FIGS. 2 to 7 are cross-sectional views illustrating a process of a method for manufacturing a 3-dimensional electronic device according to an embodiment of the inventive concept.

Referring to FIGS. 1 and 2, semiconductor chips 20 and guide blocks 30 are coupled onto a substrate 10 (S10).

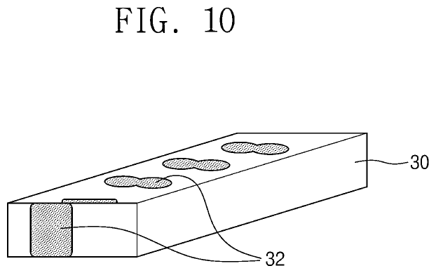

FIGS. 8 and 9 each illustrate an example of the semiconductor chips 20 in FIG. 2.

Referring to FIGS. 8 and 9, the semiconductor chips 22 may have solder bumps 22 or pads 24. The solder bumps 22 may include BGA soldering balls. Each of the pads 24 may have a flat surface. Each of the semiconductor chips 20 may include an application processor or a memory device, and an embodiment of the inventive concept is not limited thereto. Although not illustrated, the substrate 10 may be in contact with or bonded to top surfaces of the semiconductor chips 20. Bottom surfaces of the semiconductor chips 20 may be exposed from the substrate 10. The solder bumps 22 and pads 24 of the semiconductor chips 20 may be exposed from the substrate 10. That is, the solder bumps 22 and pads 24 of the semiconductor chips 20 may not be bonded to or in contact with the substrate 10.

Referring to FIG. 2 again, the guide blocks 30 may be coupled onto sidewalls of the substrate 10. The guide blocks 30 may be bonded to the sidewalls of the substrate 10 through an adhesive layer 12.

FIG. 10 illustrates an example of the guide blocks 30 in FIG. 2.

Referring to FIG. 10, each of the guide blocks 30 may have a rectangular parallelepiped shape. The guide block 30 may include a dielectric block or a polymer block. According to an embodiment, the guide block 30 may include via electrodes 32 therein. The via electrodes 32 may pass through the guide block 30. The via electrodes 32 may include hollow metal TSVs. For example, the via electrodes 32 may include cooper, and an embodiment of the inventive concept is not limited thereto.

Referring to FIGS. 1 and 3, an upper mold layer 40 and upper wires 50 may be formed on the substrate 10, the guide blocks 30, and the semiconductor chips 20 (S20). According to an embodiment, the upper mold layer 40 and the upper wires 50 may be formed using a 3D printing method. The upper mold layer 40 may include a polymer, and the upper wires 50 may include cooper. However, an embodiment of the inventive concept is not limited thereto. The 3D printing method is a method of receiving information on three-dimensionally designed objects to get outputs into a three-dimensional shape using 3D printers. The 3D printers may relatively easily create three-dimensional products using digitalized drawings, and may effectively remove the radiation-induced errors described above according to how to design three-dimensional structures. In general, 3D figures are drawn through a program such as 3D CAD which is capable of drawing the 3D figures for 3D printing. The 3D printers are already utilized in some of the manufacturing process in the aerospace industry. Recently, as 3D printing-customized small quantity batch production processes are applied, expectations of and requirements for new markets for spacecraft appearance and core components such as electronic components increase. In the 3D printing, a fabrication method is changed according to printing materials. In a stereo lithography apparatus (SLA) that is a liquid-based fabrication method, liquid polymer synthetic resin and other synthetic resins are used to be deposited in layers along the shape of an object, followed by photocuring. In a powder-based method, a process of melting or sintering a synthetic resin in powder form or a metal raw material is performed. The powder-based method includes selective laser sintering (SLS) and direct metal laser sintering (DMLS). These methods have merits that products are stronger than those undergone photocuring of liquid raw materials. In addition, in fused deposition modeling (FDM), a raw material in the form of string is melted to be deposited in layers, and this method shows similar characteristics to the liquid- or powder-based method. Among these methods, the methods of heating materials in powder form with laser to solidify the materials (SLS and DMLS) have high precision, and the method of melting solid materials to deposit the materials (FDM) is the most used due to low costs. Materials for 3D printing are extremely diverse, from insulators, such as rubber, nylon, and plastic, to metals such as stainless steel and titanium. In addition, some materials may be mixed for 3D printing. When electronic devices are fabricated using the 3D printing method, a design flow includes integration of electronic/mechanical CAD systems (mechanical computer-aided design (MCAD) and electronic computer-aided design (ECAD)) that supports each step such as specification definition, function and wiring design, component design, simulation, or volume and weight of product. An electronic design process may be characterized by the number of “steps” of the process. However, when the integration of the electronic/mechanical CAD systems is considered, the process is identified as a three-step process including functional and logic design, wiring design, and exterior design, and each of these steps is implemented through integration of MCAD and ECAD. Each of the upper mold layer 40 and the upper wires 50 may be printed in a thickness of about 1 m or less.

According to an embodiment, the upper mold layer 40 may include upper air holes 42. The upper air holes 42 may be in contact with a top surface of the substrate 10. The upper air holes 42 may be provided between the semiconductor chips 20. The upper air holes 42 may each have a semi-circular shape on a vertical view. The upper air holes 42 may block space radiation. The upper air holes 42 may have different shapes according to positions on the substrate 10. The upper air hole 42 at a center of the substrate 10 may have a large size, and the upper air hole 42 at an edge of the substrate 10 may have a small size.

Referring to FIGS. 1 and 4, additional substrates 10, semiconductor chips 20, guide blocks 30, upper mold layers 40, and upper wires 50 are further stacked on the upper mold layer 40 (S30). The substrates 10, the semiconductor chips 20, the guide blocks 30, the upper mold layers 40, and the upper wires 50 may be stacked separately in layers respectively. Alternatively, the semiconductor chip 20, the guide block 30, the upper mold layer 40, and the upper wire 50 may be formed per each of the substrates 10 separately, and then stacked in layers. However, an embodiment of the inventive concept is not limited thereto.

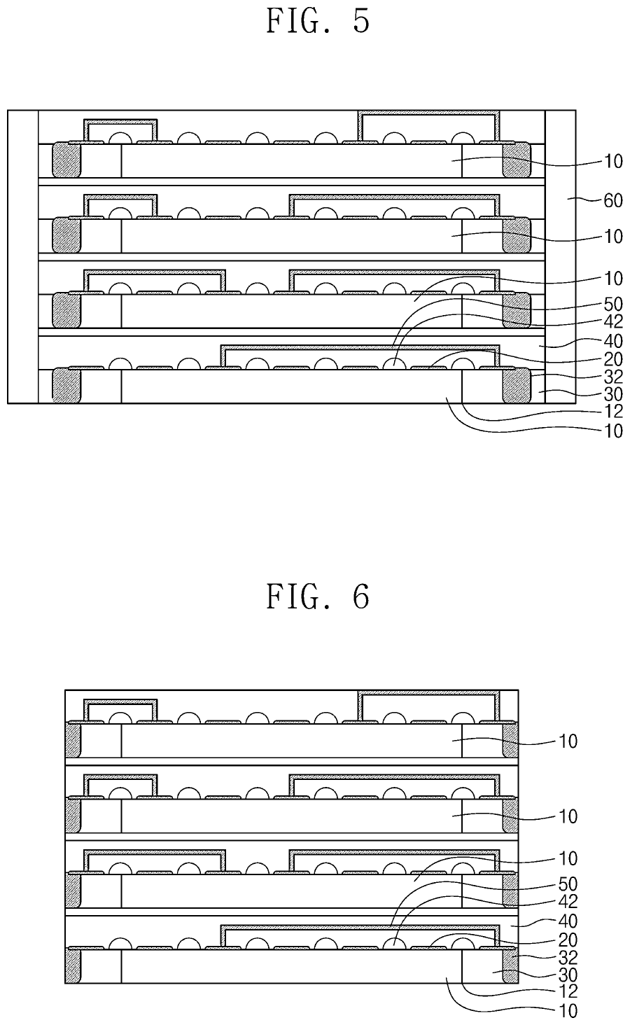

Referring to FIGS. 1 and 5, sacrificial layers 60 are formed on respective sidewalls of the guide blocks 30 and the upper mold layers 40 (S40). The sacrificial layers 60 may fix the substrates 10, the guide blocks 30 and the upper mold layers 40.

Referring to FIGS. 1 and 6, a portion of each of the guide blocks 30 and the upper mold layers 40 is sawed (S50). The via electrodes 32 of the guide blocks 30 may be exposed to the outside. The sidewalls of the guide blocks 30 and the upper mold layers 40 may be polished, and an embodiment of the inventive concept is not limited thereto.

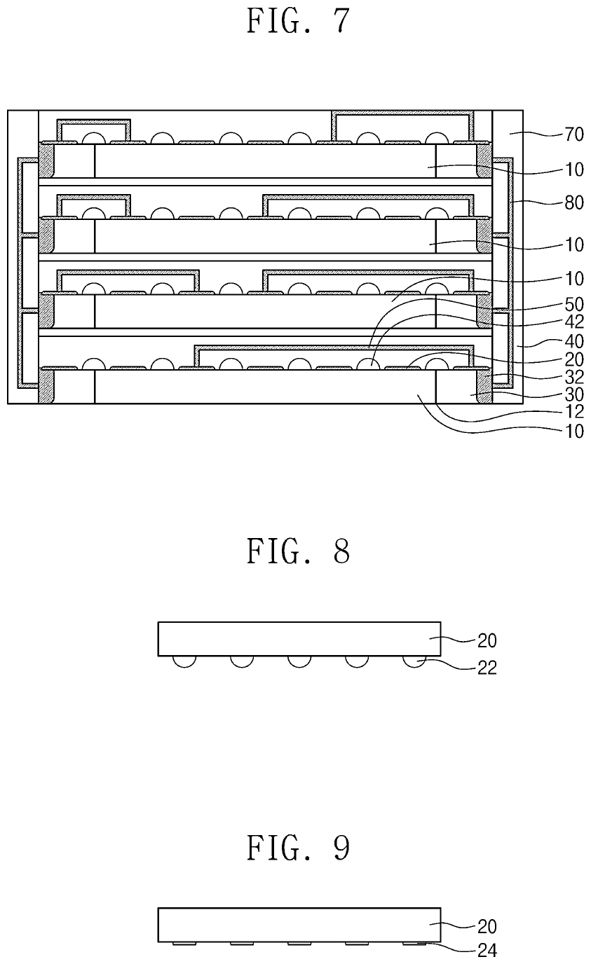

Referring to FIGS. 1 and 7, a side mold layer 70 and side wires 80 are formed on the sidewalls of the guide blocks 30 and the upper mold layers 40 (S60). The side mold layer 70 and the side wires 80 may be formed using a 3D printing method. The side mold layer 70 may have side air holes 72 on the sidewalls of the upper mold layers 40. Each of the side air holes 72 may have a larger size than the upper air hole 72. The side air hole 72 may have a semi-circular shape on a vertical view. The side air hole 72 may remove or minimize space radiation.

Thus, the method for manufacturing the 3-dimensional electronic device 100 according to an embodiment of the inventive concept may connect the upper wires 50 and the side wires 80 to the semiconductor chips 20 and the via electrodes 32, respectively, by using the 3D printing method. Accordingly, a production yield may be improved.

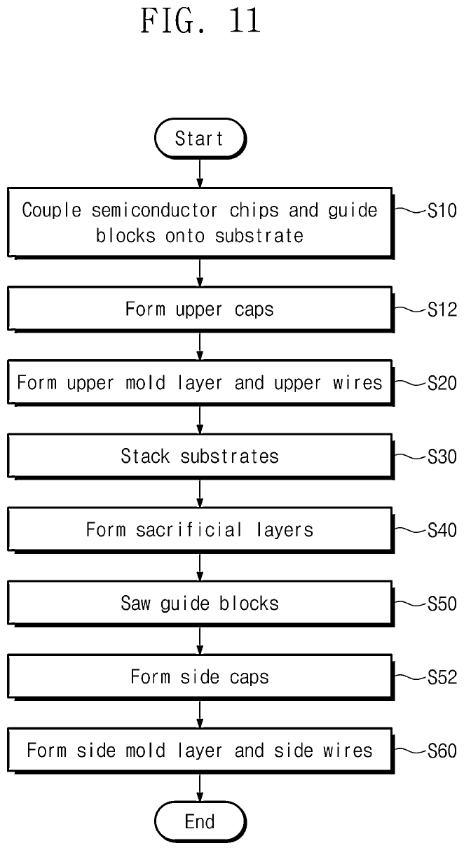

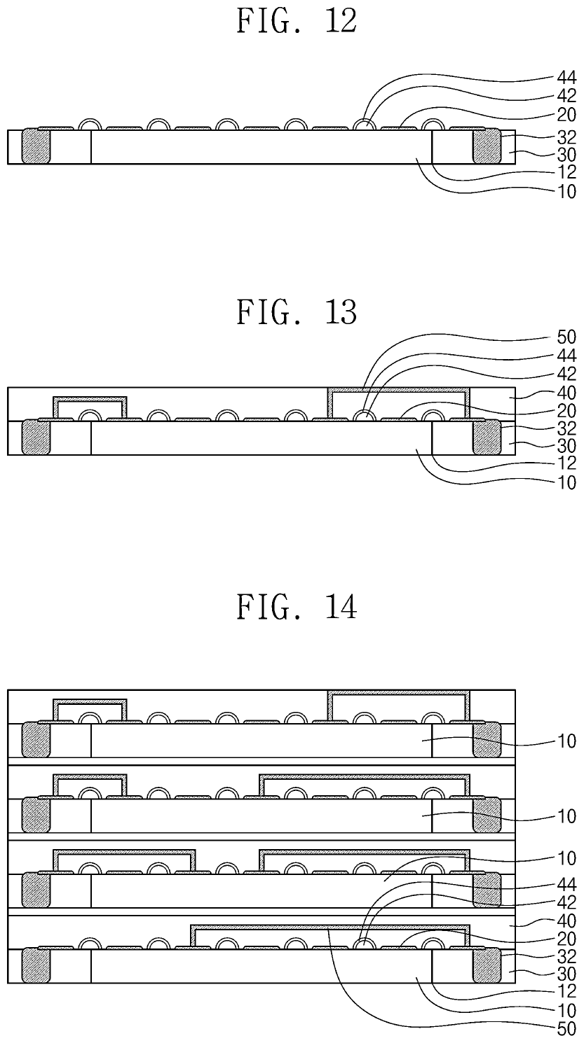

FIG. 11 illustrates a method for manufacturing a 3-dimensional electronic device according to an embodiment of the inventive concept. FIGS. 12 to 18 are cross-sectional views illustrating a process of a method for manufacturing a 3-dimensional electronic device according to an embodiment of the inventive concept.

Referring to FIGS. 2 and 11, semiconductor chips 20 and guide blocks 30 are coupled onto a substrate 10 (S10).

Referring to FIGS. 11 and 12, upper caps 44 are formed (S12). The upper caps 44 may be provided between the semiconductor chips 20. Each of the upper caps 44 may have an arc shape on a vertical view. The upper cap 44 may have a half-pipe shape. The upper caps 44 may define or have upper air holes 42 therein. The upper cap 44 may include a dielectric or a polymer.

Referring to FIGS. 11 and 13, an upper mold layer 40 and upper wires 50 are formed over the substrate 10, the guide blocks 30, the semiconductor chips 44, and the upper caps 44 (S20). According to an embodiment, the upper mold layer 40 and the upper wires 50 may be formed using a 3D printing method.

Referring to FIGS. 11 and 14, additional substrates 10, semiconductor chips 20, guide blocks 30, upper mold layers 40, upper caps 44, and upper wires 50 are further stacked on the upper mold layer 40 (S30).

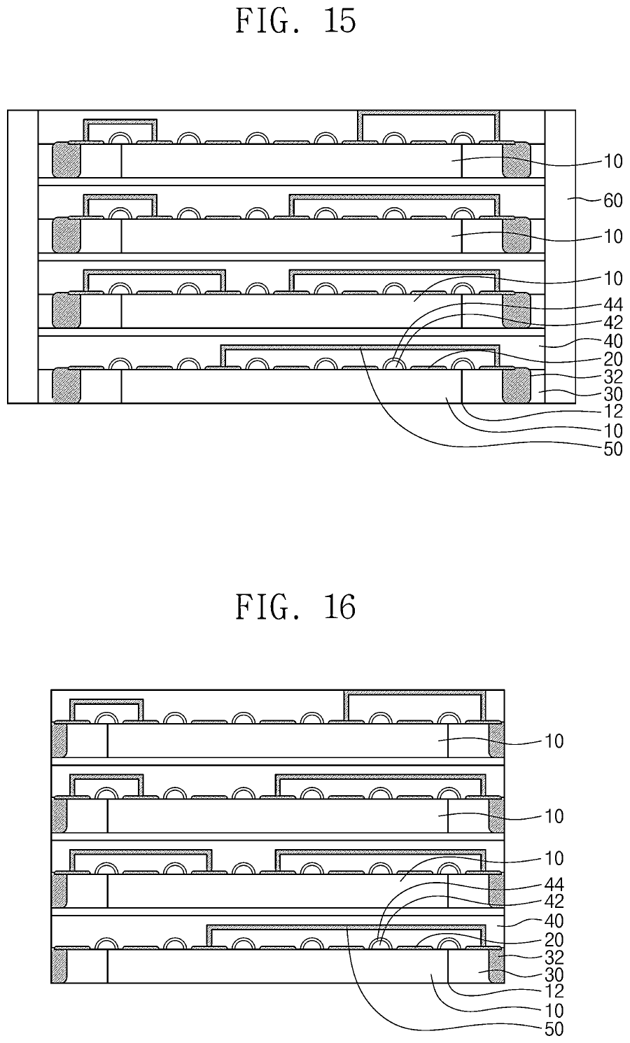

Referring to FIGS. 11 and 15, sacrificial layers 60 are formed on respective sidewalls of the guide blocks 30 and the upper mold layers 40 (S40).

Referring to FIGS. 11 and 16, a portion of each of the guide blocks 30 and the upper mold layers 40 is sawed (S50). The via electrodes 32 of the guide blocks 30 may be exposed to the outside.

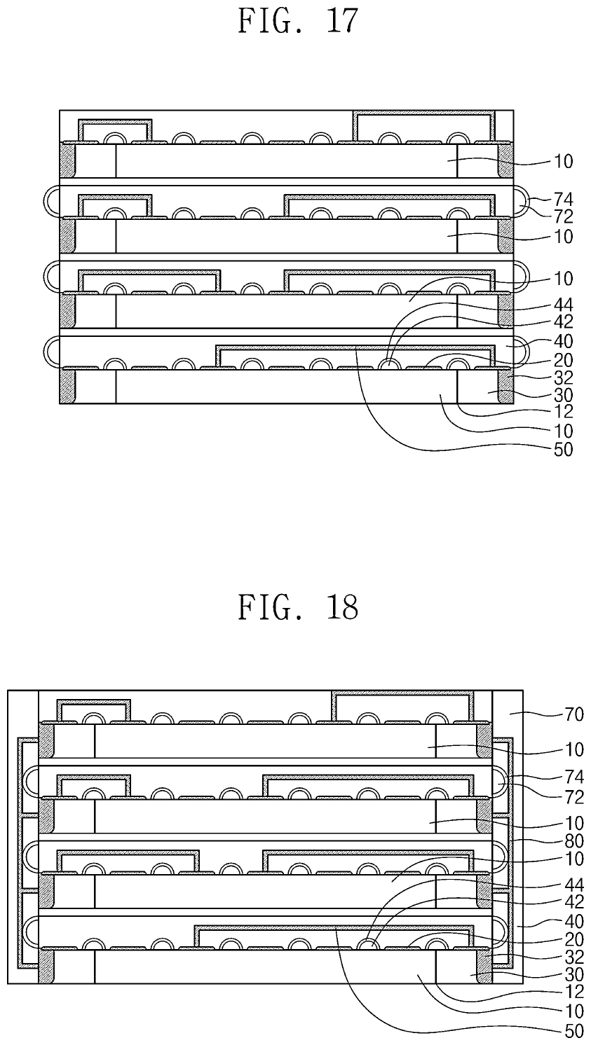

Referring to FIGS. 11 and 17, side caps 74 are formed on the sidewalls of the upper mold layers 40 (S52). The side caps 74 may be provided between the via electrodes 32. Each of the side cap 74 may have a larger size than the upper cap 44. The side cap 74 may have an arc shape on a vertical view. The side cap 74 may have a half-pipe shape. The side caps 74 may define or have side air holes 72 therein. The side cap 74 may include a dielectric or a polymer.

Referring to FIGS. 11 and 18, a side mold layer 70 and side wires 80 are formed on the sidewalls of the guide blocks 30 and the upper mold layers 40, and the side caps 74 (S60).

As described above, the method for manufacturing the 3-dimensional electronic device according to the embodiment of the inventive concept may connect the upper wires and the side wires to the semiconductor chips and the via electrodes, respectively, by using the 3D printing method. Accordingly, the production yield may be increased.

Although the embodiments of the present invention have been described, it is understood that the present invention should not be limited to these embodiments but various changes and modifications can be made by one ordinary skilled in the art within the spirit and scope of the present invention as hereinafter claimed. Therefore, it should be understood that the embodiments described above are intended to be illustrative and not for purposes of limitation in all aspects.

What is claimed is:

1. A method for manufacturing a 3-dimensional electronic device, the method comprising:
coupling semiconductor chips and guide blocks onto a substrate;
forming an upper mold layer and upper wires on the semiconductor chips and the guide blocks by using a 3D printing method;
stacking substrates other than the substrate on the upper mold layer and the upper wires;
sawing a portion of each of the guide blocks and the upper mold layer; and
forming a side mold layer and side wires on sidewalls of via electrodes of the guide blocks by using the 3D printing method.

2. The method of claim 1, wherein the semiconductor chips have pads that are exposed from the substrate.

3. The method of claim 1, wherein the coupling of the guide blocks comprises forming an adhesive layer between sidewalls of the substrate and the guide blocks.

4. The method of claim 1, wherein the upper mold layer has upper air holes between the semiconductor chips.

5. The method of claim 4, wherein the side mold layer has side air holes on a sidewall of the upper mold layer.

6. The method of claim 5, wherein each of the side air holes has a larger size than each of the upper air holes.

7. The method of claim 5, further comprising forming side caps, which define the side air holes, respectively, on the sidewall of the upper mold layer.

8. The method of claim 7, wherein the side caps are provided between the via electrodes.

9. The method of claim 4, further comprising providing upper caps, which define the upper air holes, respectively, between the semiconductor chips.

10. The method of claim 1, further comprising forming sacrificial layers on sidewalls of the guide blocks and the upper mold layer.

11. A 3-dimensional electronic device comprising:
a plurality of substrates;
semiconductor chips on each of the plurality of substrates;
guide blocks provided on sidewalls of the substrates and having via electrodes;
upper mold layers provided between the semiconductor chips and the substrates;
upper wires provided within the upper mold layers, and configured to connect the semiconductor chips to each other;
side mold layers on sidewalls of the upper mold layers and the guide blocks; and
side wires provided within the side mold layers, and configured to connect the via electrodes of the guide blocks to each other.

12. The 3-dimensional electronic device of claim 11, wherein the semiconductor chips have pads that are exposed from the substrate.

13. The 3-dimensional electronic device of claim 11, further comprising an adhesive layer between the sidewalls of the substrate and the guide blocks.

14. The 3-dimensional electronic device of claim 11, wherein each of the upper mold layers has upper air holes between the semiconductor chips.

15. The 3-dimensional electronic device of claim 11, wherein the side mold layer has side air holes on the sidewall of the upper mold layer.

16. The 3-dimensional electronic device of claim 15, wherein each of the side air holes has a larger size than each of the upper air holes.

17. The 3-dimensional electronic device of claim 15, further comprising side caps provided on the sidewall of the upper mold layer and configured to define the side air holes, respectively.

18. The 3-dimensional electronic device of claim 17, wherein the side caps are provided between the via electrodes.

19. The 3-dimensional electronic device of claim 14, further comprising upper caps provided between the semiconductor chips and configured to define the upper air holes, respectively.
